(19) United States
(12) Patent Application Publication
(10) Pub. No.: US 2008/0038906 A1
(43) Pub. Date: Feb. 14, 2008

(54) Method for Producing P-Type Ga2o3 Film and Method for Producing Pn Junction-Type Ga2o3 Film

(76) Inventors: Noboru Ichinose, Tokyo (JP); Kiyoshi Shimamura, Tokyo (JP); Kazuo Aoki, Tokyo (JP); Encarnacion Antonia Garcia Villora, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(21) Appl. No.: 11/664,438

(22) PCT Filed: Sep. 30, 2005
(86) PCT No.: PCT/JP05/18180

§ 371 Date: Mar. 30, 2007

(30) Foreign Application Priority Data
Oct. 1, 2004 (JP) 2004-290845

(51) Int. Cl. H01L 21/20

(52) U.S. Cl. 438/508; 257/E21.09

(57) ABSTRACT

Disclosed are a method for producing a p-type Ga₂O₃ film and a method for producing a pn junction-type Ga₂O₃ film which enable to form a thin film composed of a high-quality Ga₂O₃ compound semiconductor. Specifically, the pressure in a vacuum chamber (52) is reduced, and while introducing oxygen radicals, a cell (55a) is heated for producing a Ga molecular beam (90) and a cell (55b) is heated for producing an Mg molecular beam (90). Then, a substrate (25) composed of a Ga₂O₃ compound is irradiated with the Ga molecular beam (90) and the Mg molecular beam (90), so that a p-type β-Ga₂O₃ film composed of p-type β-Ga₂O₃ is grown on the substrate (25).

### TECHNICAL FIELD

The present invention relates to a method for producing a p-type Ga₂O₃ film and a method for producing a pn junction-type Ga₂O₃ film. Specifically, the invention relates to a method for producing a p-type Ga₂O₃ film and a method for producing a pn junction-type Ga₂O₃ film, which can form a thin film composed of a high-quality Ga₂O₃ system compound semiconductor.

### BACKGROUND ART

With reference to a light emitting element in an ultraviolet region, there are especially great expectations to realize, for example, a mercury-free fluorescent lamp, a photocatalyst which provides a clean environment, and a new generation DVD by which more high density recording is achieved. In view of such circumstances, a GaN-based blue light-emitting element has been realized (for example, see Patent Document 1).

However, there is a need for a shorter wavelength light source. In recent years, production of a substrate of bulk single crystal of β-Ga₂O₃ has been considered.
Patent Document 1: Japanese Patent Application Laid-Open (JP-A) No. 05-283745

However, when a thin film composed of Ga₂O₃ is epitaxial grown on a substrate composed of conventional Ga₂O₃, it shows an n-type conductivity without an acceptor, and even if an acceptor is introduced, it shows an insulating type. Thus, only Ga₂O₃ with low purity could be obtained.

Therefore, an object of the present invention is to provide a method for producing a p-type Ga₂O₃ film and a method for producing a pn junction-type Ga₂O₃ film, which can form a thin film composed of a high-quality Ga₂O₃ system compound semiconductor.

### DISCLOSURE OF THE INVENTION

### Problem to be Solved by the Invention

A first invention, in order to achieve the above object, provides a method for producing a p-type Ga₂O₃ film, including: a first step of forming a Ga₂O₃ insulating film by reducing oxygen defects; and a second step of forming a p-type Ga₂O₃ film by doping the Ga₂O₃ insulating film with an acceptor.

It is preferable that the first and second steps are performed at the same time.

It is preferable that the first step includes a step of supplying active oxygen and Ga metal on a Ga₂O₃ substrate, and that the second step includes a step of supplying Mg metal to the Ga₂O₃ substrate.

Preferably, the first and second steps are performed by an MBE method.

The Ga metal to be used is preferred to have a purity of 6N or more.

The active oxygen is preferably supplied by a radical gun.

A second invention, in order to achieve the above object, provides a method for producing a pn junction-type Ga₂O₃ film, including a first step of forming a Ga₂O₃ insulating film by reducing oxygen defects; a second step of forming a p-type Ga₂O₃ film by doping the Ga₂O₃ insulating film with an acceptor; and a third step of forming an n-type Ga₂O₃ film by doping the Ga₂O₃ insulating film with a donor.

It is preferable that the first and second steps are simultaneously performed in a predetermined time interval, and that the first and third steps are simultaneously performed in a certain time interval different from the predetermined time interval.

Preferably, the first to third steps are performed on a predetermined surface of a substrate composed of a Ga₂O₃ system compound semiconductor.

The predetermined surface is preferably a (100) surface.

According to the first and second inventions, a thin film composed of a high-quality Ga₂O₃ system compound semiconductor can be formed.

This application is based on Japanese Patent Application No. 2004-290845, the entire contents of which are incorporated herein by reference.

### BRIEF DESCRIPTION OF THE DRAWINGS

FIG. 1 depicts an MBE apparatus for use in formation of a p-type semiconductor layer, where (a) is a perspective view including a partial cutaway section and (b) is an enlarged view of a substantial part of the MBE apparatus.

FIG. 2 is a diagram showing a device for measuring a Seebeck coefficient.

### BEST MODE FOR CARRYING OUT THE INVENTION

A light emitting element according to an embodiment of the present invention is constituted by forming a p-type Ga₂O₃ film and a n-type Ga₂O₃ film on a predetermined surface of a substrate, for example, on a (100) surface.

(Method for Forming β-Ga₂O₃ Substrate)

A β-Ga₂O₃ substrate to be used in the invention is prepared by forming a single crystal of β-Ga₂O₃ by a FZ method and then cleaving it so as to create a (100) surface.

(Method for Forming p-type β-Ga₂O₃ Film)

Hereinafter, a method for forming a p-type β-Ga₂O₃ film will be described.

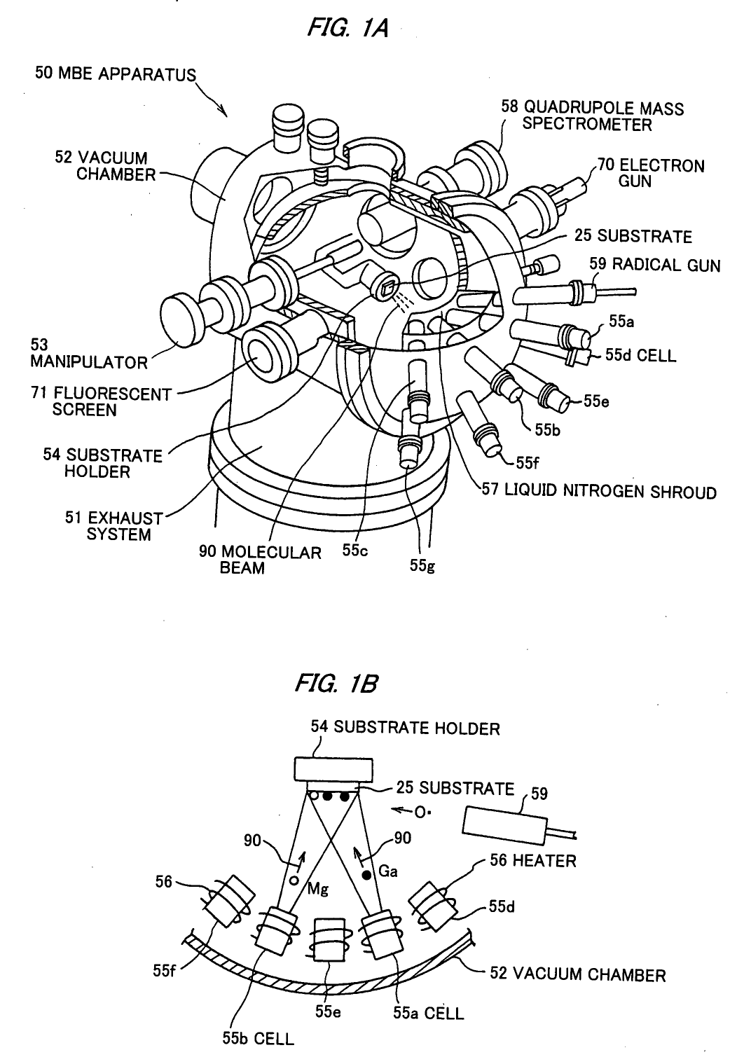

FIG. 1 shows a molecular beam epitaxy (MBE) apparatus 50 for use in formation of a p-type β-Ga₂O₃ film, wherein (a) is a perspective view including a partial cutaway section and (b) is an enlarged view of a substantial part of the MBE apparatus. The MBE apparatus 50 includes a vacuum chamber 52 connected with an exhaust (not shown) via an exhaust system 51, and a substrate holder 54 which is provided in the vacuum chamber 52 and supported by a manipulator 53 so as to be rotatable and movable, the holder 54 allowing the substrate 25 to be attached.

The vacuum chamber 52 includes: a plurality of cells 55 (55a, 55b, . . . ) which are formed so as to face the substrate 25 and house the atoms and molecules constituting a thin film respectively; a reflective high-energy electron diffraction (RHEED) electron gun 70 from which an electron beam is emitted to impinge on the substrate 25; a fluorescent screen 71 formed on a wall of the vacuum chamber 52 which faces the electron gun 70 across the substrate 25, the fluorescent screen 71 allowing a diffraction pattern of the electron beam emitted from the electron gun 70 to be projected thereon; a liquid nitrogen shroud 57 which prevents the inside of vacuum chamber 52 from reaching a high temperature; a quadrupole mass spectrometer 58 which analyzes the surface of the substrate 25; and a radical gun 59 which supplies a radical. The vacuum chamber 52 is set to conditions of an ultrahigh vacuum or an extreme high vacuum, preferably at least 1×10⁻⁹ torr.

The cell 55 is configured so as to be filled with acceptors composed of metal materials such as Ga to be grown on the substrate 25 as a thin film and Mg and also to heat the contents by a heater 56. The cell 55 has a shutter (not shown) which is configured to be closed when the cell is unnecessary.

The radical gun 59 supplies energy such as heat, light, and radiation to oxygen in order to generate radical oxygen (active oxygen).

Here, a film is formed on the substrate 25 using the MBE apparatus 50 as follows. First, the β-Ga₂O₃ substrate 25 is fitted to the substrate holder 54, and then Ga metal with a purity of 6N is placed in the cell 55a while Mg metal as an acceptor is placed in the cell 55b. Next, the exhaust system 51 is operated to reduce the pressure in the vacuum chamber 52 to 5×10⁻⁹ torr.

The cells 55a and 55b are then heated to a predetermined temperature while radical oxygen is injected through the radical gun 59 so as to achieve radical oxygen concentrations of 1×10⁻⁴ to 1×10⁻⁷ torr, which results in the molecular beam 90 of Ga and Mg. When the substrate 25 is irradiated with the molecular beams 90 of Ga and Mg, layers of β-Ga₂O₃ grow on a (100) surface of the substrate 25.

(Examination of p-type β-Ga₂O₃ Film)

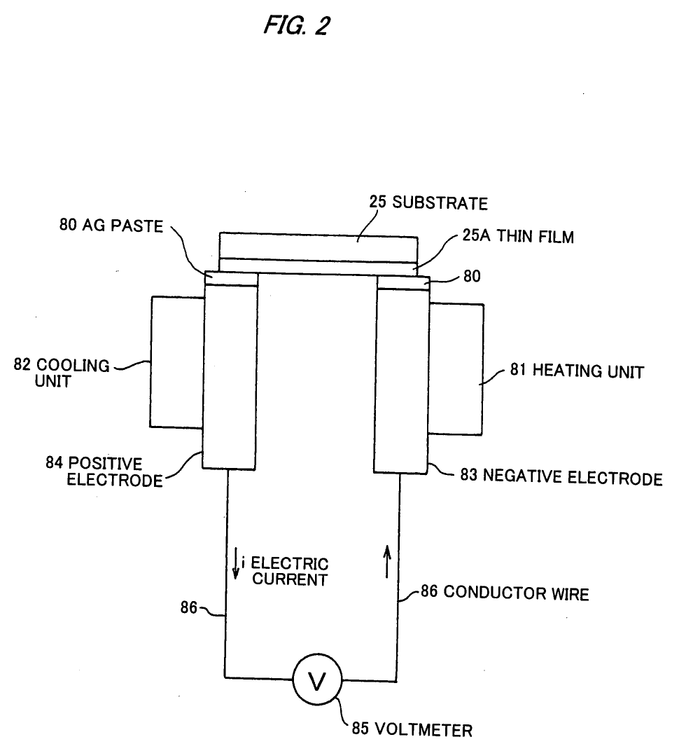

FIG. 2 is a diagram showing a device for measuring a Seebeck coefficient. In order to measure a Seebeck coefficient, one end of the substrate 25 at which a thin film 25A has been formed by a heating unit 81 is heated and the other end of the substrate 25 is cooled by a cooling unit 82, to thereby measure an electromotive force between the heating unit 81 and the cooling unit 82 with respect to the thin film 25A. Here, the thin film 25A is a β-Ga₂O₃ film formed as described above.

As a result of measuring the formed β-Ga₂O₃ film, a negative Seebeck coefficient showing the tendency for a p-type semiconductor was obtained.

(Method for Forming n-Type β-Ga₂O₃ Film)

The above-mentioned MBE apparatus 50 and metals as donors in place of acceptors are used to form a n-type β-Ga₂O₃ film. As a result, a pn junction-type β-Ga₂O₃ film composed of a p-type β-Ga₂O₃ film and an n-type β-Ga₂O₃ film can be formed.

The above-mentioned β-Ga₂O₃, i.e. a Ga₂O₃ system compound semiconductor, may be composed of Ga oxide whose principal component is Ga to which one or more kinds selected from the group consisting of Cu, Ag, Zn, Cd, Al, In, Si, Ge, and Sn is/are added. The effect of these additive elements is to control the lattice constant or bandgap energy. For example, a Ga oxide which is defined as (AlₓIn_{y}Ga_{(1-x-y)})₂O₃ (where, 0≦X<1, 0≦y<1, 0≦X+y<1) can be used.

### Effects of the Embodiment

According to the embodiment, a high-quality β-Ga₂O₃ system compound semiconductor film indicating p-type conductivity could be formed. For this reason, when the high-quality β-Ga₂O₃ system compound semiconductor film is used for a light emitting element, the lattice constant of a substrate is matched to that of a p-type β-Ga₂O₃ film because the substrate corresponds to the p-type β-Ga₂O₃ film as β-Ga₂O₃. Therefore, deterioration of crystal quality of the β-Ga₂O₃ film can be suppressed and reduction in the rate of emission can be minimized.

(Modifications)

A p-type β-Ga₂O₃ film may be formed by an MOCVD method which employs a metal organic chemical vapor deposition (MOCVD) device besides the above-mentioned MBE method. Namely, examples of a source gas to be used in the invention include an oxygen gas, N₂O, TMG (Trimethylgallium), and Cp₂Mg (biscyclopentadienyl-magnesium). In addition to He, examples of a career gas to be used herein include rare gases such as Ar and Ne and an inert gas such as N₂. In order to form an n-type β-Ga₂O₃ film, SiH₄ (monosilane) is used in place of Cp₂Mg.

Alternatively, a p-type β-Ga₂O₃ film which shows p-type conductivity may be formed by forming an β-Ga₂O₃ insulating film and then introducing an acceptor into the film.

### INDUSTRIAL APPLICABILITY

According to a method for producing a p-type Ga₂O₃ film and a method for producing a pn junction-type Ga₂O₃ film in the present invention, a thin film composed of a high-quality Ga₂O₃ system compound semiconductor can be formed.

1. A method for producing a p-type Ga₂O₃ film, comprising:
a first step of forming a Ga₂O₃ insulating film by reducing oxygen defects; and
a second step of forming a p-type Ga₂O₃ film by doping the Ga₂O₃ insulating film with an acceptor.

2. The method for producing a p-type Ga₂O₃ film according to claim 1, wherein the first and second steps are performed at the same time.

3. The method for producing a p-type Ga₂O₃ film according to claim 1, wherein the first step includes a step of supplying active oxygen and Ga metal to a Ga₂O₃ substrate, and the second step includes a step of supplying Mg metal to the Ga₂O₃ substrate.

4. The method for producing a p-type Ga₂O₃ film according to claim 1, wherein the first and second steps are performed by an MBE method.

5. The method for producing a p-type Ga₂O₃ film according to claim 3, wherein the Ga metal to be used has a purity of 6N or more.

6. The method for producing a p-type Ga₂O₃ film according to claim 3, wherein the active oxygen is supplied by a radical gun.

7. A method for producing a pn junction-type Ga₂O₃ film, comprising:
a first step of forming a Ga₂O₃ insulating film by reducing oxygen defects;
a second step of forming a p-type Ga₂O₃ film by doping the Ga₂O₃ insulating film with an acceptor; and
a third step of forming an n-type Ga₂O₃ film by doping the Ga₂O₃ insulating film with a donor.

8. The method for producing a pn junction-type Ga₂O₃ film according to claim 7, wherein the first and second steps are simultaneously performed in a predetermined time interval, and the first and third steps are simultaneously performed in a certain time interval different from the predetermined time interval.

9. The method for producing a pn junction-type Ga₂O₃ film according to claim 7, wherein the first to third steps are performed on a predetermined surface of a substrate composed of a Ga₂O₃ system compound semiconductor.

10. The method for producing a pn junction-type Ga₂O₃ film according to claim 9, wherein the predetermined surface is a (100) surface.
